(19) United States
(12) Patent Application Publication
(10) Pub. No.: US 2013/0295507 A1
(43) Pub. Date: Nov. 7, 2013

(54) PROCESSES TO FORM AQUEOUS PRECURSORS, HAFNIUM AND ZIRCONIUM OXIDE FILMS, AND HAFNIUM AND ZIRCONIUM OXIDE PATTERNS

(71) Applicants: Douglas A. Keszler, Corvallis, OR (US); Kai Jiang, Corvallis, OR (US); Jeremy Anderson, Corvallis, OR (US)

(72) Inventors: Douglas A. Keszler, Corvallis, OR (US); Kai Jiang, Corvallis, OR (US); Jeremy Anderson, Corvallis, OR (US)

(73) Assignees: EDUCATION ON BEHALF OF OREGON STATE UNIVERSITY, Corvallis, OR (US); STATE OF OREGON ACTING BY AND THROUGH THE STATE BOARD OF HIGHER

(21) Appl. No.: 13/997,121

(22) PCT Filed: Dec. 23, 2011
(86) PCT No.: PCT/US11/67252

§ 371 Date: Jun. 21, 2013

Related U.S. Application Data
(60) Provisional application No. 61/426,762, filed on Dec. 23, 2010.

(51) Int. Cl. G03F 7/004

(52) U.S. Cl. CPC G03F 7/0042
USPC 430/270.1; 423/608

(57) ABSTRACT

Embodiments of a method for synthesizing aqueous precursors comprising Hf⁴⁺ or Zr⁴⁺ cations, peroxide, and a monoprotic acid are disclosed. The aqueous precursors are suitable for making HfO₂ and ZrO₂ thin films, which subsequently can be patterned. The disclosed thin films are dense and continuous, with a surface roughness of ≦0.5 nm and a refractive index of 1.85-2.0 at λ=550 nm. Some embodiments of the disclosed thin films have a leakage-current density ≦20 nA/cm² at 1 MV/cm, with a dielectric breakdown ≧3 MV/cm. The thin films can be patterned with radiation to form dense lines and space patterns.

### CROSS REFERENCE TO RELATED APPLICATIONS

This application claims the benefit of the earlier filing date of U.S. Provisional Application No. 61/426,762, filed Dec. 23, 2010, which is incorporated herein by reference.

### ACKNOWLEDGMENT OF GOVERNMENT SUPPORT

Development of the inventions described herein was at least partially funded with government support through U.S. National Science Foundation grant CHE-0847970 and Air Force Research Lab grant FA8650-05-1-5041. The government has certain rights in the invention.

### FIELD

Disclosed embodiments concern the synthesis of aqueous precursors that can be deposited to form a coating and processed to high-quality HfO₂ and ZrO₂ thin film or patterned to very high resolution with radiation. The disclosure further relates to methods for making inorganic films and patterned layers that can be used to form elements of devices and/or a resist for facilitating the patterning of other materials.

### BACKGROUND

Hafnium oxide and zirconium oxide have many desirable properties for the formation of functional elements. For example, they are technologically important as optical coatings and as thin-film components of electronic devices. The commercial production of these coatings and films is currently restricted to vapor deposition methods. There is a need for new solution-based precursors and methods for fabricating these coatings and films that can enable low-cost large area coverage and high-throughput roll-to-roll manufacturing. Solution-based methods, already known for deposition of hafnium oxide and zirconium oxide, produce coatings and films that are disposed to porosity, cracks, and rough surfaces. These defect properties are inherently related to volume changes that occur as high levels of additives/stabilizers are expelled from the films during heating. To alleviate the extent of these defects, oxide film thickness <15 nm is favored, though cracks typically manifest above 550° C. To produce thicker films and stacks, multiple coatings of oxide layers <10 nm are favored with each coating requiring thermal processing at high temperatures (400-600° C.). Therefore, the thermal budget and process complexity become increasingly prohibitive for all except the thinnest films. Since the solution-deposited films are highly susceptible to processing, it is difficult to variably control the thickness while retaining any specific characteristic. The challenge is greater if multiple characteristics are simultaneously targeted. Overall, the physical structures of these products, as well as the associated high-temperature processing, have inhibited the use of solution methods for the production of zirconium oxide and hafnium oxide coatings and films. In particular, film characteristics such as rough surfaces and pores have prevented critical control of optical and electronic properties in devices. Thus, hafnium oxide and zirconium oxide coatings and films with highly desirable properties have not previously been achieved with known solution precursors and methods.

Electron-beam resists and photoresists are key chemicals used for manufacturing integrated circuits. These resists are organic polymers. When properly exposed and developed, they mask portions of a substrate, allowing transfer of complex patterns with very high integrity. Building faster circuits calls for radiation-sensitive resists that enable the production of small feature sizes, e.g., <30 nm, and high-integration densities. Design and development of such resists, particularly with polymers, is a significant challenge. Strict requirements with respect to film thickness, film adhesion, etch resistance, thermal stability, radiation absorption, contrast, and sensitivity must be met for high-volume manufacturing.

An alternative approach to developing such radiation-sensitive resists is found in PCT Publication WO 2009120169 A1 to Keszler et al. and U.S. Pat. Publ. 2011/0293888 A1 to Stowers et al. This approach involves the aqueous chemistry of inorganic ions, e.g., Hf⁺ and Zr⁴⁺, to address the limitations of polymer systems. The inorganic systems readily satisfy requirements for ultra-thin and uniform coatings, high-etch resistance, high-radiation absorption, and conventional wafer-track processing. Challenges remain, however, in improving process stability, resist sensitivity, and resist contrast, while reducing process complexity.

New aqueous precursors and coating materials for hafnium oxide and zirconium oxide film fabrication simultaneously address these resist challenges. Hence, the precursors and coating materials represent a fundamentally new approach for addressing a plurality of commercial uses.

### SUMMARY

In a first aspect, the disclosure pertains to an aqueous precursor composition comprising an aqueous solvent having dissolved hafnium or zirconium, peroxide, and monoprotic acid (HX) with a ratio of hafnium/X or zirconium/X>0.5.

In a further aspect, the disclosure pertains to a method for preparing an aqueous precursor solution containing hafnium or zirconium, monoprotic acid, and peroxide, comprising dissolution of a hafnium or zirconium salt in water, precipitation of hafnium or zirconium at high pH, centrifugation and washing to remove counterions, followed by dissolution in a monoprotic acid solution, e.g., HNO₃(aq), HA(aq), or HAO₄(aq), where A=Cl, Br, or I, containing peroxide.

In a further aspect, the disclosure pertains to a method for preparing an aqueous precursor solution containing hafnium or zirconium, monoprotic acid, and peroxide, comprising dissolution of a hafnium or zirconium salt in water, addition of peroxide, precipitation of hafnium or zirconium at high pH, centrifugation and washing to remove counterions, followed by dissolution in a monoprotic acid solution.

In another aspect, the disclosure pertains to a method for the formation of a hafnium or zirconium oxide film. In some embodiments, the method comprises annealing a coating layer at a temperature from about 50° C. to about 800° C. in which the coating layer comprises hafnium or zirconium and monoprotic acid (HX) with a ratio of hafnium/X or zirconium/X>0.5.

In another aspect, the disclosure pertains to a method for the formation of hafnium or zirconium oxide patterns following exposure to an electron-beam, laser, ultra-violet, or extreme ultra-violet (generally defined as a wavelength ranging from 10 nm to 200 nm) radiation source.

### BRIEF DESCRIPTION OF THE DRAWINGS

FIG. 1 is a graph showing ZrO₂ film thickness as a function of precursor concentration. The concentration corresponds to that of Zr⁴⁺

FIG. 2 is a series of x-ray diffraction patterns for HfO₂ films annealed at selected temperatures for 1 h.

FIG. 3 is a series of FT-IR spectra of ˜200-nm HfO₂ films, and EPMA (electron probe microanalysis) data with atomic percentages relative to Hf (inset). “ND” means “not detectable”.

FIGS. 4a-4d are scanning electron microscopy images for HfO₂ films annealed at (a, b) 400° C. and (c, d) 600° C. for 1 hour.

FIG. 5 is a graph showing experimental and modeled x-ray reflectivity (XRR) patterns for an 8.3-nm HfO₂ film on silicon annealed at 400° C.

FIG. 6 is a graph showing the temperature dependence of density and surface roughness examined via XRR.

FIG. 7 is a series of experimental and modeled ellipsometric spectra represented by symbols and solid lines, respectively, for a 400° C.-annealed HfO₂/SiO₂ stack.

FIG. 8 is a series of refractive index dispersion curves of HfO₂ films following 1-hour thermal anneals.

FIG. 9 is a graph showing representative current-voltage characteristics for HfO₂ films annealed in air for 1 hour.

FIGS. 10a and 10b are graphs showing representative I_{D}−V_{DS} (FIG. 10a), log(I_{D})−V_{GS}(V_{DS}=10 V) (FIG. 10b) and log(I_{G})−V_{GS} curves (FIG. 10b) for a thin-film transistor (TFT) with a HfO₂ gate dielectric and a sputtered IGZO channel. (V_{GS} is stepped from 6-20 V in 2 V increments for the I_{D}−V_{DS} curve.)

FIG. 11 is a graph of contrast curves for electron beam exposure of hafnium peroxide nitrate (solid line) and hafnium peroxide sulfate (dashed line). The hafnium peroxide nitrate is developed with dilute nitric acid (1 M) and the hafnium peroxide sulfate is developed with tetramethylammonium hydroxide (2.8 M).

FIG. 12 is a photograph showing line and space patterns written with electron-beam exposure of hafnium peroxide nitrate coating materials. Patterns with half-pitches of 14, 16, 18, 20, 22, and 26 nm were formed. The patterns were developed in nitric acid (HNO₃(aq), 1 M).

### DETAILED DESCRIPTION

HfO₂ and ZrO₂ thin films are widely used as coatings for laser optics^{1,2} and as gate dielectrics in advanced transistor technologies.³⁻⁵ To fulfill most application requirements, the films should be smooth and dense in a thickness range from <10 nm to several-hundred nanometers. Consequently, advanced vapor methods, such as electron-beam evaporation,⁶ chemical vapor deposition (CVD),^{7,8} sputtering,^{9,10} and atomic layer deposition (ALD)¹¹⁻¹³ have been favored for film deposition. Even with these sophisticated techniques, it can be challenging to produce films with the desired properties. For example, energy-assisted deposition is generally required to produce highly dense films for optics. Post-deposition anneals of dielectric films are often necessary to lower defect concentrations. Annealing, however, generally induces crystallization of HfO₂, producing in a dielectric unwanted grain-boundaries, associated leakage-current and impurity diffusion pathways, and surface or interfacial roughness, leading to thermal losses and poor device reliability. In many cases, the tolerable range of deposition conditions or “process window,” is quite small. In addition, scaling vapor deposition of these oxide films to large areas with high uniformity remains problematic.¹⁴

High-speed printing or coating of thin-film materials from solution precursors (inks) offers a potentially simple and low-energy opportunity for realizing large-area fabrication of electronic and electro-optical devices. Of course, such printing is largely predicated on the availability of precursors that smoothly and efficiently transform into high-quality films.

Thin-film HfO₂ deposition through conventional sol-gel routes via spin- or dip-coating has been described in several reports. For example, hafnia sol precursors have been made by mixing HfCl₄ into ethanol or 1-methoxy-2-propanol followed by hydrolysis and peptization with acid.¹⁵⁻¹⁷ Similar colloidal suspensions have been produced by using HfOCl₂ as the starting material.² Precursors have also been prepared by stabilizing hafnium ethoxide or hafnium pentadionate in acetylacetone/ethanol.¹⁸⁻²⁰ Each of these methods has relied on the preparation of large sol particles or use of a metal-organic reagent. Because of the high activation energy for inter-particle densification and the incomplete expulsion of organic residues, these methods are predisposed to production of highly porous films. After annealing at 450° C., refractive indices are commonly reported to be approximately 1.7 (λ=550 nm), corresponding to a porosity >26%. Even though high-temperature annealing may facilitate densification of the deposited sols, it also leads to HfO₂ crystallization and grain-boundary formation as annealing temperatures reach 500° C. As insulators, these films exhibit high leakage-current densities near 10⁻⁵ A/cm² at 1 MV/cm,^{16,21} three orders of magnitude higher than that required for a thin-film transistor (TFT) gate dielectric. To produce higher-quality material, a presumed surface sol-gel method has been described, which involves the use of a precursor of hafnium n-butoxide dissolved in toluene/ethanol.¹⁴ In this method, an attempt is made to mimic the self-limiting reactions of ALD by inhibiting grain boundary, porosity, and cracking problems through sequential deposition of ultra-thin layers. This approach, however, offers a slow deposition rate (0.6 nm/cycle), while associated island growth is manifested as surface roughness exceeding 1 nm.

High-quality oxide films may be deposited by using highly controlled inorganic aqueous precursors. Examples include HfO₂₋ₓ(SO₄)ₓ (HafSOx)²² and Al₂O₃₋₃ₓ(PO₄)₂ₓ (AlPO)²³ as dielectrics, ZnO²⁴ and (InGaZn)ₓO_{y}²⁵ as semiconductors, and HafSOx as a directly imaged hardmask for writing sub-20 nm features.²⁶ These films exhibit properties comparable to those achieved via advanced vapor techniques. By promoting hydrolysis and condensation of metal species, while inhibiting the formation of large colloids, wet precursor coatings are converted smoothly to dense films.

The precursor chemistry disclosed herein allows a unique densification of the film, enabling its use as a high-performance dielectric. The dielectric performance is assessed both through capacitor and thin-film transistor studies and correlated to the structural, morphological, and optical properties of the films.

As used herein, “comprising” means “including” and the singular forms “a” or “an” or “the” include plural references unless the context clearly dictates otherwise. The term “or” refers to a single element of stated alternative elements or a combination of two or more elements, unless the context clearly indicates otherwise.

### I. DEFINITIONS

The following explanations of terms and abbreviations are provided to better describe the present disclosure and to guide those of ordinary skill in the art in the practice of the present disclosure. As used herein, “comprising” means “including” and the singular forms “a” or “an” or “the” include plural references unless the context clearly dictates otherwise. The term “or” refers to a single element of stated alternative elements or a combination of two or more elements, unless the context clearly indicates otherwise.

Unless explained otherwise, all technical and scientific terms used herein have the same meaning as commonly understood to one of ordinary skill in the art to which this disclosure belongs. Although methods and materials similar or equivalent to those described herein can be used in the practice or testing of the present disclosure, suitable methods and materials are described below. The materials, methods, and examples are illustrative only and not intended to be limiting. Other features of the disclosure are apparent from the following detailed description and the claims.

Unless otherwise indicated, all numbers expressing quantities of components, molecular weights, percentages, temperatures, times, and so forth, as used in the specification or claims are to be understood as being modified by the term “about.” Unless otherwise indicated, non-numerical properties such as amorphous, crystalline, homogeneous, and so forth as used in the specification or claims are to be understood as being modified by the term “substantially,” meaning to a great extent or degree. Accordingly, unless otherwise indicated, implicitly or explicitly, the numerical parameters and/or non-numerical properties set forth are approximations that may depend on the desired properties sought, limits of detection under standard test conditions/methods, limitations of the processing method, and/or the nature of the parameter or property. When directly and explicitly distinguishing embodiments from discussed prior art, the embodiment numbers are not approximates unless the word “about” is recited.

Annealing: A process in which a material is heated to a specified temperature for a specified period of time and then gradually cooled. The annealing process removes internal strains from previous operations, and can eliminate distortions and imperfections to produce a stronger and more uniform material.

Counterion(s): The ion, or ions, accompanying another ionic species to provide electric neutrality. For example, in NaOH, Na⁺ is the counterion to OH⁻.

Dielectric breakdown: The formation of electrically conducting regions in an insulating material exposed to a strong electric field.

Extreme ultraviolet: Electromagnetic radiation having a wavelength ranging from 10 nm to 200 nm.

Leakage-current density: Leakage current is the undesirable flow of current through or over the surface of an insulating material or insulator, or the flow of direct current through a poor dielectric in a capacitor. Leakage current can also be defined as any current that flows when the ideal current is zero. Leakage current density is the leakage current per unit area.

Precursor: An intermediate compound or molecular complex. A precursor participates in a chemical reaction to form another compound.

Relative Density: A ratio of the density (mass of a unit volume) of a substance to the density of a reference material. If the relative density of a substance is less than one, then it is less dense than the reference; if greater than 1, then it is denser than the reference.

Root mean square (RMS): A statistical measure determined by calculating the square root of the mean of the squares of the values. In a case of n values {x₁, x₂, . . . , xₙ}, the RMS is calculated by the equation:

$${x}_{rms} = \sqrt{\frac{1}{n} ( {x}_{1}^{2} + {x}_{2}^{2} + ⋯ + {x}_{n}^{2} )}$$

Ultraviolet: Electromagnetic radiation having a wavelength ranging from 10 nm to 400 nm.

### II. PRECURSOR CHEMISTRY

Embodiments of a method for making a zirconium oxide or hafnium oxide precursor solution include dissolving a zirconium or hafnium salt in water, forming a precipitate through addition of an aqueous base, removing unwanted counterions from the precipitate, dissolving the precipitate in a monoprotic acid, and adding aqueous hydrogen peroxide following one or more of the preceding steps.

Suitable zirconium salts include zirconium oxide chloride and zirconium oxide nitrate. Suitable hafnium salts include hafnium oxide chloride and hafnium oxide nitrate. Dissolution of the salt in water produces a tetrameric species having four metal atoms at the corners of a square plane and doubly bridged by hydroxo ligands.

In some embodiments, the aqueous base is ammonia or sodium hydroxide. Rapid addition of the aqueous base induces hydrolysis and condensation, leading to a gelatinous precipitate. Other researchers have precipitated zirconia nuclei of 15-30 Å after refluxing/modest drying.⁴⁵⁻⁴⁷ Rapidly induced precipitation conditions favor nearly amorphous precipitates; assuming only modest particle growth during centrifuging and washing, ordered regions less ≦2 nm, in diameter are expected. The basic square structure of the tetramer is preserved during condensation by olation (a process by which metal ions form polymeric oxides in aqueous solution through the formuation of polynuclear complexes in which hydroxyl groups function as bridge).^{45,48} In certain embodiments, the precipitate is substantially amorphous, with ordered regions of less than 5 nm in diameter, such as ≦2 nm. Thus, in some embodiments, the aqueous base is added in a batchwise, or substantially batchwise, manner. The precipitate is washed and then centrifuged or filtered to remove byproduct salts.

The precipitate is dissolved in a monoprotic acid, HX, such as HNO₃(aq), HA(aq), or HAO₄ (aq), where A=Cl, Br, or I. In some embodiments, a sufficient quantity of acid is added to produce Hf/X or Zr/X>0.5. In certain embodiments, Hf/X or Zr/X=1 completely dissolves the precipitate.

Dissolution of the precipitate with the monoprotic acid, however, is quite slow, requiring up to two weeks in some instances when nitric acid was used to dissolve a hafnium precipitate. Simultaneous addition of H₂O₂(aq) shortens this time to approximately 12 hours, indicating the peroxo group plays an important role in dissociating aggregated particles and species by coordinating to the metal ion. Precursors containing peroxide also produce much more uniform films than those containing only X⁻, (e.g., nitrate). Moreover, it has been demonstrated that the low energies required for decomposition of the peroxo ligands enable prompt condensation during the formation of the film and consequently low-temperature densification.^{26,50} Hence, the introduction of peroxide into the precursor solution provides substantial benefits.

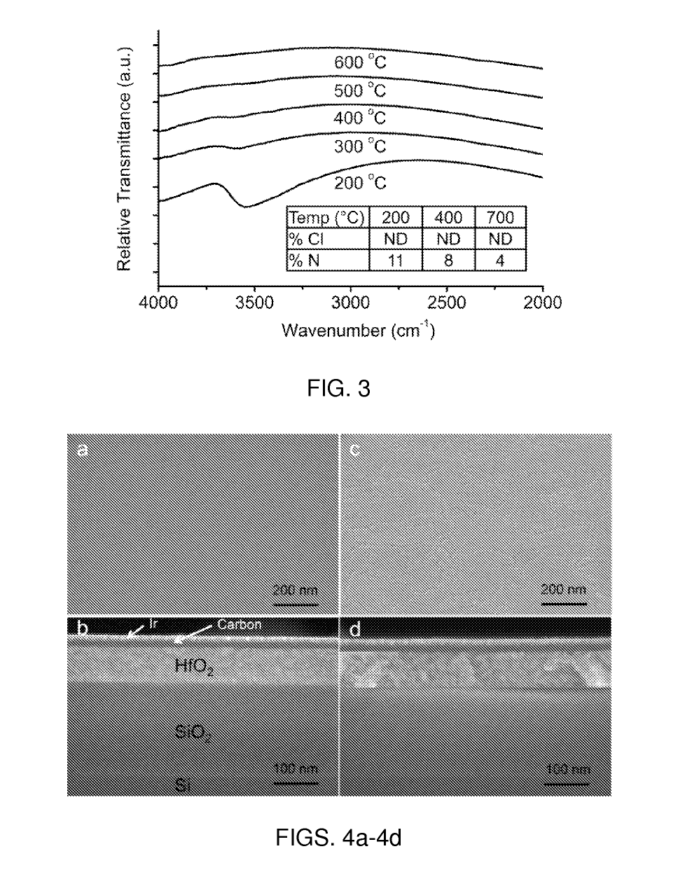

A flow diagram representing one embodiment of a method for synthesizing a an HfO₂ precursor is depicted in Scheme 1. The preparation of the corresponding ZrO₂ precursor follows the same steps, as the aqueous chemistry of Zr⁴⁺ is substantially the same as Hf⁴⁺. In Step (1), the reagent HfOCl₂.8H₂O is simply dissolved in water. It has been well established that this dissolution preserves the tetrameric species, Hf₄(OH)₈(H₂O)₁₆⁸⁺.⁴¹⁻⁴⁴ Rapid addition of NH₃(aq) induces hydrolysis and condensation, leading to a gelatinous precipitate. Thin-film EPMA measurements (FIG. 3 inset) revealed the absence of Cl⁻ in the films. Hence, the centrifuge and wash procedures effectively remove Cl⁻ from the solutions. The overall process of precipitation, centrifugation, and washing, is summarized as Step (2). By adding HNO₃(aq), or similar monoprotic acid, e.g., HCl(aq) or HCOOH(aq), at approximately one mole equivalent with respect to Hf, the precipitate can be completely dissolved. Considering the weak complexing ability of NO₃⁻ toward Hf,⁴⁹ and assuming the tetrameric structure remains intact, the species existing after dissolution of the precipitate with HNO₃(aq) can be represented by the general formula [Hf₄(OH)₁₂.yH₂O]ₘ^{4m+}. The value of “y” represents a level of hydration different from that of the precipitate. The value of “m” is less than about 30 on the basis of nuclei no larger than 2 nm. This dissolution, as Step (3a), is further represented by the reaction of Eq. (1), where for clarity, the formulas of the Hf species are simplified.

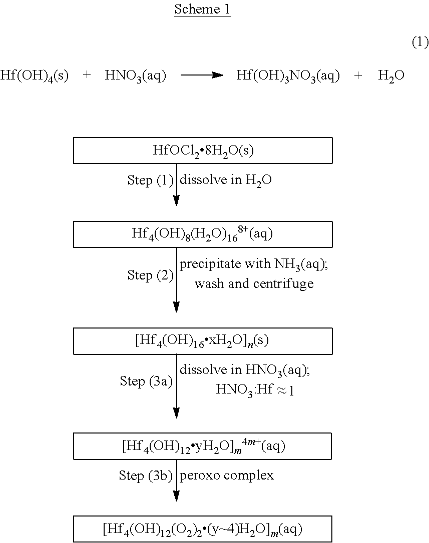

Unlike the well-established peroxo chemistry of the early transition elements Ti, V, Nb, Mo, and W, the corresponding chemistry of Hf and Zr is less developed. From equilibrium studies coordination of the peroxo ligand to Zr in HClO₄(aq) was proposed as early as 1949.⁵¹ In more recent studies, the Zr/peroxide ratio in the same system was determined to be 2:1 by titration methods.⁵² We also note a recent report of a ZrO₂ precursor prepared by dissolving ZrO(NO₃)₂ in a mixture of H₂O₂(aq) and NH₃(aq) for thin-film deposition.⁵³ Based on our calculations using the Partial Charge Model (PCM),⁵⁴ we find peroxo complexing to Hf is possible during the dissolution process, as depicted as Step (3b) in Scheme 1.

All the aforementioned chemical interactions are critical design elements for this thin film precursor. Precipitates are created rapidly, and despite their inherently high reactivity, are separated and solvated with peroxide and minimal acid. Species are stabilized without the use of bulky organic complexing ligands so that the precursor can be converted to solid with minimal disruption.

In another synthesis route, as depicted in Scheme 2, H₂O₂(aq) was added to dissolved HfOCl₂ before the precipitation step to control the size of the precipitated species. This procedure results in a precipitate that dissolves in a monoprotic acid in approximately 15 seconds as compared with 12 hours for dissolving the precipitate according to the process of Scheme 1. Substantially the same results are obtained by using ZrOCl₂ in place of HfOCl₂ or the nitrate salts ZrO(NO₃)₂ or HfO(NO₃)₂.

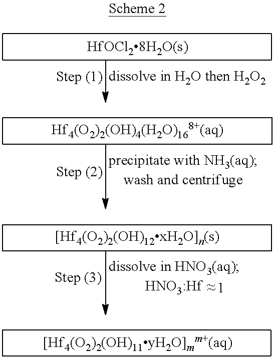

Embodiments of the disclosed precursor solutions have a ratio of Zr/X or Hf/X>0.5 (X═NO₃⁻, Cl⁻, Br⁻, I⁻, ClO₄⁻, BrO₄⁻, or IO₄⁻), such as a ratio of 0.8-1.5 or 1-1.2. The disclosed precursor solutions also have a Zr/O₂²⁻ ratio or a Hf/O₂²⁻ ratio of between 0.02 and 2, such as a ratio from 0.02-1.5, 0.02-1, 0.05-2, 0.05-1, or 0.5-2.

### III. COATING MATERIAL/THIN FILMS

Embodiments of the disclosed precursor solutions are suitable for making HfO₂ and ZrO₂ thin films. The aqueous precursors can be applied to substrates as coating materials and thin films by methods such as spin coating, spray coating, aerosol chemical vapor deposition, ink-jet printing, and dip coating. A person of ordinary skill in the art will appreciate that any of a number of substrate materials potentially can be used to practice embodiments of the present disclosure. Solely by way of example, and without limitation, suitable substrates include semiconductor materials, metals, glass, polymeric materials, and combinations thereof. In certain embodiments, the substrate is silicon. In some embodiments, at least one surface of the substrate is hydrophilic. In one embodiment, the substrate is treated to render the surface hydrophilic prior to applying the coating material. Substrates may be rendered by hydrophilic by treating them in an O₂ plasma or a UV/ozone system, or by immersing them in a solution containing H₂SO₄(aq) and H₂O₂ (aq).

In certain embodiments, a substrate may be coated with tantalum prior to depositing the coating material. Tantalum-coated substrates can be used to fabricate capacitors for testing purposes, e.g., to establish dielectric constants, breakdown, and/or leakage-current density.

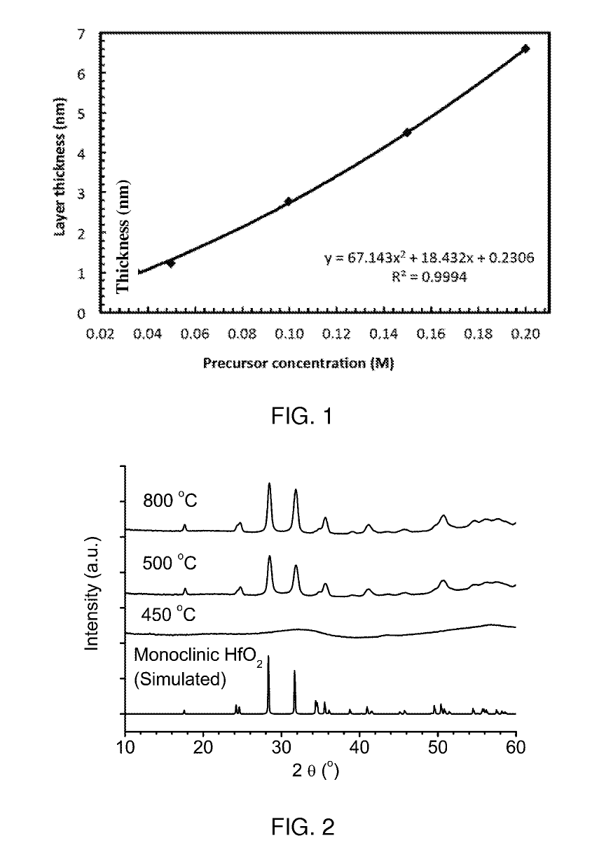

In one embodiment, a single layer of coating material is deposited onto a substrate. In another embodiment, a plurality of coating material layers is deposited onto the substrate. In some embodiments, each layer has a thickness ranging from 2 nm to 50 nm, depending at least in part on the precursor solution's concentration and the deposition conditions. As shown in FIG. 1, individual film thickness can be set by controlling the Zr or Hf concentration in the precursor solution. Film thickness can be further set by depositing a plurality of individual layers by spin or dip coating, controlling the deposition time with aerosol CVD, or managing pulses with ink-jet printing. In certain embodiments, each layer has a thickness from 2-40 nm, such as from 2-20 nm or 4-10 nm. When depositing a plurality of layers, the coated substrate may be heated for a brief period of time between layers. For example, the coated substrate may be heated at 40-200° C., or 40-150° C. for up to 5 minutes, such as at 150° C. for 1 minute or at 80° C. for 2 minutes.

After the final layer is deposited, the coated substrate is annealed to expel water, excess oxygen (e.g., from peroxide), and monoprotic acid, thereby increasing the coating material density and forming a HfO₂ or ZrO₂ film on the substrate. In some embodiments, annealing includes heating at 200-800° C. for 1-120 minutes, such as from 30-120 minutes, 30-90 minutes, or 60 minutes. In one embodiment, a 0.2 M Hf-based precursor solution produced a film having a thickness of 8 nm after annealing. In embodiments wherein the film is to be patterned, the coated substrate is heated at 40-200° C., such as at 40-150° C., for up to 5 minutes prior to patterning.

Embodiments of the disclosed precursor solutions produce continuous, dense HfO₂ and ZrO₂ thin films. In some embodiments, HfO₂ thin films have a density from 7 g/cm³ to 10 g/cm³, such as from 7 g/cm³ to 9 g/cm³ or 7.1 g/cm³ to 8.8 g/cm³. In one embodiment, a hafnia film annealed at 400° C. had a density of 8.71 g/cm³, which corresponds to a relative density of 0.86, considering single-crystal HfO₂ as the reference (density=10.12 g/cm³).

In some embodiments, ZrO₂ films have a density of 4 g/cm³ to 6 g/cm³, such as from 4 g/cm³ to 5.6 g/cm³, 5 g/cm³ to 5.6 g/cm³, or 5 g/cm³ to 5.5 g/cm³. In one embodiment, a zirconia film annealed at 300° C. had a density of 5.11 g/cm³, which corresponds to a relative density of 0.90, considering single-crystal monocline ZrO₂ as the reference (density=5.68 g/cm³).

The films also exhibit extreme smoothness with no visible cracks or voids when viewed with a scanning electron or atomic force microscope. In some embodiments, the coating material is annealed at a temperature between 200° C. and 800° C., and the resulting thin film has a root mean square roughness of ≦0.7 nm, such as ≦0.5 nm, ≦0.4 nm, or ≦0.3 nm measured by atomic force microscopy (AFM). In some embodiments, the coating material is annealed at a temperature of less than 500° C., and the thin film has a roughness of ≦0.3 nm, which is indistinguishable above the AFM instrument noise floor. In one embodiment, a HfO₂ film had a roughness of 0.25 nm when annealed at 200° C. and a roughness of 0.40 nm when annealed at 500° C., as measured by x-ray reflectivity. In another embodiment, a ZrO₂ film had a roughness of 0.15 nm when annealed at 300° C.

Advantageously, embodiments of the disclosed thin films are substantially free of unwanted counterions, including anions from the hafnium and zirconium salts as well as cations from the base used in precipitation. For example, when the starting salt is hafnium oxide chloride or zirconium oxide chloride, the resulting thin film has a chloride concentration below the noise threshold of the electron probe microanalysis instrument, i.e., <0.5% relative to Hf or Zr.

Some embodiments of the disclosed HfO₂ and ZrO₂ thin films have a refractive index (λ=550 nm) of 1.8-2.0, such as 1.85-1.95 when the thin film is annealed at a temperature from 300° C. to 600° C. As described below in Example 2, these refractive indices correspond to bulk volume fractions of 75-90% for the annealed films, with voids comprising water in the 300° C.-annealed film and voids comprising air in the 400° C. and 600° C.-annealed films.

Thus, some embodiments of the disclosed HfO₂ and ZrO₂ thin films further comprise water. In certain embodiments, the thin film further comprises up to 25% (v/v) water.

Some embodiments of the disclosed HfO₂ and ZrO₂ thin films have a relative dielectric constant of 12-15 at 1 kHz, such as a dielectric constant of 12-13. In some embodiments, a HfO₂ or ZrO₂ thin film has a thickness greater than 30 nm, and a leakage-current density ≦20 nA/cm² at 1 MV/cm, a dielectric breakdown ≧3 MV/cm, or both. In certain embodiments, a HfO₂ or ZrO₂ thin film has a thickness greater than 30 nm, and a leakage-current density ≦12 nA/cm² at 1 MV/cm, a dielectric breakdown ≧3.5 MV/cm, or both.

### IV. PATTERNING

Embodiments of the disclosed coating materials can be patterned with a selected radiation, such as ultraviolet light, x-ray radiation, or electron-beam radiation. The radiation-patterned coating material can have a high contrast with respect to material properties, such that development of a latent image can be successful to form lines with very low line-width roughness and adjacent structures with a very small pitch. When patterned, embodiments of the disclosed thin films are suitable for use as a thin film-component in an optical or electronic device (e.g., a thin film transistor (TFT), a field effect transistor (FET), a metal-insulator-semiconductor (MIS) capacitor, or metal-insulator-metal (MIM) capacitor) or as a resist for facilitating patterning of other materials.

In some embodiments, compositions of these patterning materials include a polyatomic anion such as sulfate, borate, or phosphate. The binding strengths of these polyatomic anions to zirconium and hafnium are competitive with that of the peroxide ligands. As a result, over time the polyatomic ligands can displace the peroxide ligands, leading to instabilities in the coating material precursor and the reproducibility of patterning structures with a very small pitch.

In contrast, the nitrate ligand, NO₃⁻, and associated conjugate bases of related monoprotic strong acids exhibit weak binding to zirconium and hafnium. Therefore coating material precursor solutions containing these ligands exhibit a greater stability relative to those previously described, since the polyatomic ligand will not readily displace peroxide.

The method of making the coating material precursor also substantively affects the performance of the coating material in patterning. For example, the dissolution rate of the precipitate formed through the process of Scheme 1 (addition of peroxide after precipitate formation) dissolves in a dilute nitric acid solution over a period of 12 hours, while the precipitate formed through the process of Scheme 2 (addition of peroxide before precipitation) dissolves in a dilute nitric acid solution over a period of 15 seconds. This high solubility can be retained in the coating material to afford enhanced patterning capabilities.

A substrate is coated with a precursor material by any suitable means, including spin coating, spray coating, aerosol deposition, dip coating, or ink-jet printing to produce a layer of coating material on the substrate. The coated substrate is at least partially dried by heating before patterning the coating material. For example, the coated substrate may be heated at 50-200° C. for up to 5 minutes. In certain embodiments, the coated substrate is heated at 75-100° C. for 1-3 minutes before patterning. In some embodiments, the coating material has a thickness from 2 nm to 40 nm prior to patterning.

The coating material can be patterned by exposure to a pattern of radiation. Suitable radiation sources include, but are not limited to, ultraviolet light, extreme ultraviolet light, laser beam, and electron beam sources. In one embodiment, the radiation source is a high-voltage electron beam tool with a lithography system. In another embodiment, the radiation source is an extreme ultraviolet lithography tool. In another embodiment, the radiation source is a laser capable of producing light having a wavelength of 193 nm (e.g., an argon-fluoride laser). In some embodiments, the coating material is exposed to an electron beam at a dose of from 10 μC/cm² to 500 μC/cm².

In some embodiments, patterning is achieved by placing a mask between the radiation source and the coated substrate. The mask allows exposure of uncovered portions of the coated substrate, thereby facilitating transfer of complex patterns with very high integrity. In other embodiments, patterning is achieved by moving a radiation source (e.g., an electron beam or laser beam) in a predetermined pattern across the coated substrate such that only areas of the coated substrate exposed to the radiation source are patterned.

Exposure to radiation condenses the coating at the exposed locations, rendering the exposed coating less soluble or substantially insoluble in dilute acid.

Typically, the coated substrate is heated after exposure to radiation. For example, the coated substrate may be heated to at least 50° C. for 1-5 minutes, such as for 2 minutes, after exposure. Unexposed areas of the coating material may be removed by contacting the coating material with a developer solution such as dilute acid, e.g., 1 M HNO₃(aq), for a period of time effective to dissolve unexposed coating material, thereby producing a patterned film on the substrate. In some embodiments, the coating material is contacted with dilute acid for up to 3 minutes. The patterned film is rinsed to remove developer solution and dissolved coating material, and then heated to dry the patterned film. The patterned film may be heated at a temperature between 200° C. and 500° C. In one embodiment, the patterned film was heated to 250° C. for 5 minutes.

In some embodiments, dense lines and space patterns less than 50 nm, less than 25 nm, less than 20 nm, or less than 15 nm half pitch (i.e., half the distance between identical features in an array) can be produced. In one embodiment, features as small as 14-nm half pitch were produced using an electron beam (see, e.g., FIG. 12).

### V. EXAMPLES

### Example 1

### Preparation of Precursors

Method 1:

HfOCl₂.8H₂O (Alfa Aesar, 98+%) was dissolved in H₂O to a Hf concentration of 0.12 M. 6.7 mL of 1-M NH₃(aq) (Mallinckrodt, ACS) was added to 20 mL of the solution with vigorous stirring (pH=8.5). The resulting precipitate was centrifuged and then washed with H₂O to remove Cl⁻ and ammonia. Rinse and separation steps were repeated five times until no precipitates were observed after mixing the supernatant with AgNO₃(aq). After these steps, the yield of Hf was measured to be 98%. Finally, 5 mL of 10-M H₂O₂(aq) (Mallinckrodt, ACS) and 1.4 mL of 2-M HNO₃(aq) (EDS, ACS) were added to the precipitates and stirred for approximately 12 h to obtain a clear precursor solution having pH=0.7. The final Hf concentration was 0.2 M with a NO₃⁻/Hf ratio of 1.2. At room temperature, the precursor solution was found to remain clear for at least one year. 18-MΩ Millipore water was used for each preparation.

Method 2:

HfOCl₂.8H₂O (Alfa Aesar, 98+%) was dissolved in H₂O and H₂O₂ (30% Mallinckrodt, ACS) to a Hf concentration of 0.2 M and H₂O₂ concentration of 2.4 M. Subsequently, 2 M NH₃(aq) (Mallinckrodt, ACS) was added to the above solution with a NH₃/Hf ratio of 3.2 and stirred vigorously (pH=9.0). The resulting precipitate was centrifuged and then washed with H₂O to remove Cl⁻ and ammonia. Rinse and separation steps were repeated five times. After these steps, the yield of Hf was measured to be 95%. Finally, 2-M HNO₃(aq) (EDS, ACS) were added to the precipitate with a HNO₃/Hf ratio of 1 and stirred immediately. H₂O or H₂O₂ was added for dilution purpose. A clear precursor solution was thus obtained. The final Hf concentration was 0.2 M. At room temperature, the precursor solution was been found to remain clear for at least one year. 18-MΩ Millipore water was used for each preparation.

### Example 2

### Deposition of Coating Material

Prior to deposition, all substrates were rinsed with H₂O followed by a 10-min ash in an O₂ plasma at 10 mTorr, 5 sccm O₂, and 0.75 W/cm². Films were deposited on substrates by spin-coating, followed by an immediate hot-plate cure at 150° C. for 1 min. This procedure was repeated until the desired thickness was obtained. A 1-hour oven anneal in air at selected temperatures in the range 200-800° C. completed the process. For standard characterization, a 0.2-M Hf solution was spin-coated at 3000 rpm for 30 s, generating ˜8 nm/cycle after a final anneal at 400° C. Film thickness for one deposition cycle could be readily adjusted in the range of 4-10 nm through precursor dilution and spin-coating parameters. Thicker coatings up to 40 nm were deposited after concentrating the standard precursor, though these films were not characterized extensively.

Structural and Chemical Characterization.

For X-ray diffraction (XRD), transmission Fourier transform infrared (FT-IR), and electron-probe microanalysis (EPMA) measurements, thin films were deposited on Si wafers coated with 200 nm of thermally grown SiO₂. XRD data were collected with a Rigaku RAPID diffractometer generating Cu Ku radiation. Transmission FT-IR spectra were collected on a Nicolet 5PC spectrometer with a bare Si/SiO₂ substrate as reference. EPMA data were obtained with a Cameca SX-50 with wavelength dispersive spectrometers and gas-flow proportional detectors with P-10 gas. Intensities of O Kα, Si Kα, Cl Kα, N Ku, Hf Mα, and Zr Lα were collected at accelerating voltages of 8, 12, and 16 kV and averaged over 10 positions on each sample. Si, Ca₅(PO₄)₃Cl, BN, Hf, and Zr were used as standards. Raw intensities were corrected by a procedure detailed by Donovan and Tingle.²⁶ Elemental compositions were quantified by comparing experimental k-ratios to simulated values using StrataGEM thin-film composition analysis software.

XRD data for films heated at temperatures up to 800° C. are illustrated in FIG. 2. No discernable diffraction peaks are evident for films annealed at temperatures ≦450° C. for 1 hour. As the temperature rises through and above 500° C., the monoclinic form of HfO₂ crystallizes, persisting to the maximum temperature (800° C.) investigated. This crystallization behavior is similar to many conventional sol-gel derived films,^{15,19,21} where the initial stage of crystallization has been observed near 450° C. via electron-diffraction experiments.¹⁹ Crystallization behavior of vapor-deposited films varies by deposition method and conditions. In some cases, as-deposited films from CVD,⁸ sputtering,¹⁰ and ALD²⁸ were observed to be polycrystalline.

FT-IR spectra were collected to monitor the hydration levels of films as a function of temperature. Spectra covering the energy range 2000-4000 cm⁻¹ are illustrated in FIG. 3. The primary absorption feature of interest is the broad band centered at approximately 3500 cm⁻¹, which is assigned to O—H stretching modes.

The intensity of this band decreased significantly when the annealing temperature rose from 200 to 300° C., indicating a major portion of the aqua and hydroxo groups were lost in this temperature range. The O—H absorption band was not observed after annealing the film at 500° C., where the film crystallized as HfO₂. Additionally, features associated with nitrate absorption²⁹ at 1560 and 1280 cm⁻¹ were clearly evident only for films annealed below 300° C.

EPMA data were collected to further determine the residual counterion (Cl⁻ and NO₃⁻) contents of the films, cf., inset FIG. 3. The measured Cl concentrations (<0.5% relative to Hf) correspond to the noise threshold of the instrument for all the samples measured, supporting the chemical observations for AgCl precipitation that most of the Cl⁻ was removed through the precipitation, rinse, and centrifuge steps of the precursor synthesis. The atomic percentages of N ranged from approximately 10% to 4% with increasing temperatures. Because the atomic ratio of NO₃⁻ to Hf was 1.2 in the precursor solution, it is apparent that a significant fraction of NO₃⁻ was eliminated during the deposition and subsequent annealing. For comparison, Southon and co-workers³⁰ heated a nitrate-based zirconia gel and determined most nitrate was lost by 400° C., according to Raman spectroscopy. It is reasonable to assume that our rapidly converted thin films expel nitrate groups more readily. Quantifying the content of a light atom such as N via EPMA, however, is quite challenging; additional analytical techniques may be used to further quantify any NO₃ residue or adsorbed N₂.

Morphology and Density.

Thin films for scanning electron microscopy (SEM) and atomic force microscopy (AFM) were also deposited on Si/SiO₂ substrates. Thin films for X-ray reflectivity (XRR) were deposited on p-type Si substrates. Surface roughness was evaluated by using a Digital Instruments Nanoscope III Multimode atomic force microscope operated in contact mode with a Veeco NP-20 SiNₓ probe at a scan frequency of 1.5 Hz. A low-pass filter and a second-order plane fit were applied to all samples to limit high-frequency noise and sample tilt. XRR data were collected with Cu Ku radiation (45 kV, 40 mA) on a Philips PW/3040 diffractometer. The incident beam was conditioned by using a 0.05-mm divergence slit. The exit beam was conditioned with a 0.1-mm detector slit. Low-angle reflections from 0.3-5° (2θ) were collected in 0.01° steps at 1 s/step. Analyses were conducted with X'Pert Reflectivity V1.0 software using sample thickness, surface roughness, and density as fitting parameters.

Surface and cross-section SEM images of films annealed at 400 and 600° C. are shown in FIGS. 3a-3d. The surface of the film annealed at 400° C. was so smooth that no features were discernible in the top-view SEM image (FIG. 4a). The high-resolution cross-section SEM image (FIG. 4b) revealed a continuous and dense film ˜85-nm thick. For the crystallized film annealed at 600° C., grain growth and grain boundary formation become apparent in both top-view and cross-section SEM images (FIGS. 4c and 4d). The thickness of this film was about 80 nm from FIG. 4d. Notably, all of the films exhibited extreme smoothness and continuity without visible cracks and voids after experiencing the strong forces associated with drying and crystallization.

Consistent with the SEM results, contact-mode AFM imaging of films annealed below 500° C. revealed no distinguishable features of the films above the instrument noise floor, resulting in root-mean-square (RMS) roughness values consistently ≦0.3 nm over a 2×2 μm² area for HfO₂ and ≦0.4 nm for ZrO₂. Even for a well-crystallized HfO₂ film annealed as high as 800° C., the roughness was only 0.7 nm.

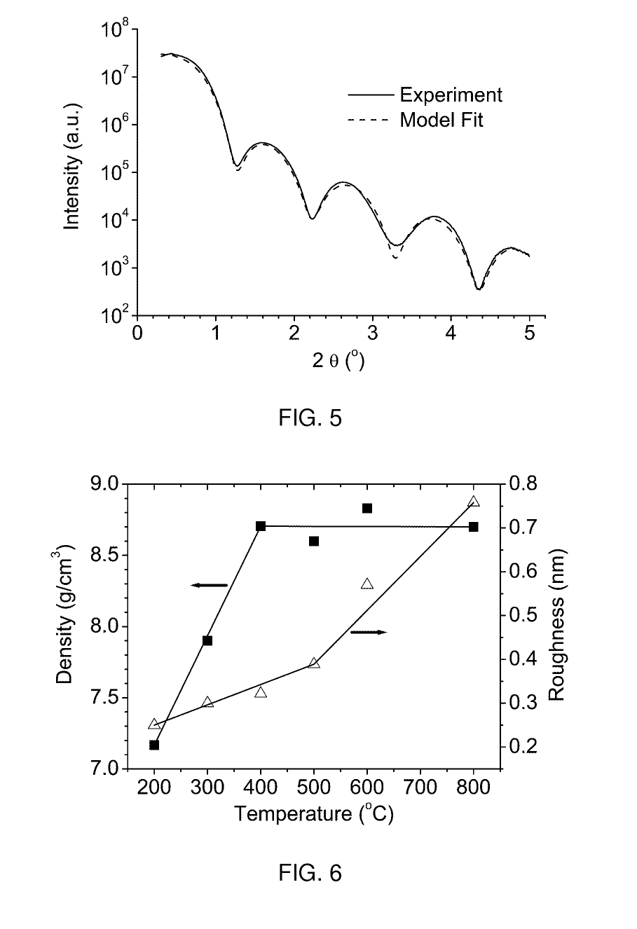

XRR data were collected mainly to obtain film roughness and densities. For all films annealed in the range of 200-800° C., Kiessig fringes in the patterns were found to extend beyond the maximum angle (2θₘₐₓ=5°) set for the analysis. By fitting the experimental curves, thicknesses, surface roughness, and density were generated for each film. An XRR pattern for a 400° C.-annealed film, along with the model fit, is displayed in FIG. 5 as an example of the data and model fit. Generated surface roughness and density following each temperature are plotted in FIG. 5. The surface roughness of an HfO₂ film annealed at 200° C. was 0.25 nm, and the surface roughness of a ZrO₂ film annealed at 300° C. was 0.15 nm. The roughness of the HfO₂ film increased by approximately 0.15 nm as the annealing temperature increased to 500° C. Above 500° C., roughness increased sharply as grain growth was enhanced. The surface roughness values are consistent with those obtained from AFM measurements.

The density of the HfO₂ film increased significantly from 7.17 to 8.71 g/cm³ as the annealing temperature rose from 200 to 400° C., and varied little at higher temperatures. Since the density evolution above 400° C. has not been thoroughly investigated, the precise density trend and potential maximum value cannot be inferred from FIG. 6. Still, the value of 8.71 g/cm³ for the 400° C.-annealed film corresponds to 86% of the single-crystal density of monoclinic HfO₂ (10.12 g/cm³),³¹ and is comparable to those reported (8.50 and 9.23 g/cm³) for ALD HfO₂ films.^{32,33} When annealed at 300° C., the density of a ZrO₂ film was 5.11 g/cm³, which corresponds to 90% of the single-crystal value (5.68 g/cm³). In contrast, from metal-organic based solution precursors, corresponding ZrO₂ films achieved comparable relative densities only after annealing above 1000° C., whereupon roughness increased dramatically.³⁴

Optical Properties.

HfO₂ films were spin-coated on Si/SiO₂ substrates for spectroscopic ellipsometry (SE) measurements. Data were collected at the incident angles of 65, 70, and 75° in the range 300-1000 nm by using an HS-190 spectroscopic ellipsometer (J.A. Woolam Co.). SE provides the complex reflectance ratio ρ=tan(Ψ)exp(iΔ), where tan(Ψ) is the amplitude ratio upon reflection, and Δ is the phase difference. The ellipsometric data were analyzed by using the VASE software package. The analysis is based on least-square regression analysis to obtain the unknown fitting parameters. Using appropriate optical models, the parameters were varied to minimize the difference between the calculated Ψ, Δ values and the experimental data. The difference is represented by the mean square error (MSE). The transmission and reflection spectra from 390 to 850 nm were measured at near-normal incidence by using a double-grating spectrometer with a broadband Xe source and a Si-photodiode detector. The thickness and wavelength-dependent refractive index, n(λ), were obtained from analysis of the interference fringes in the reflection and transmission spectra.

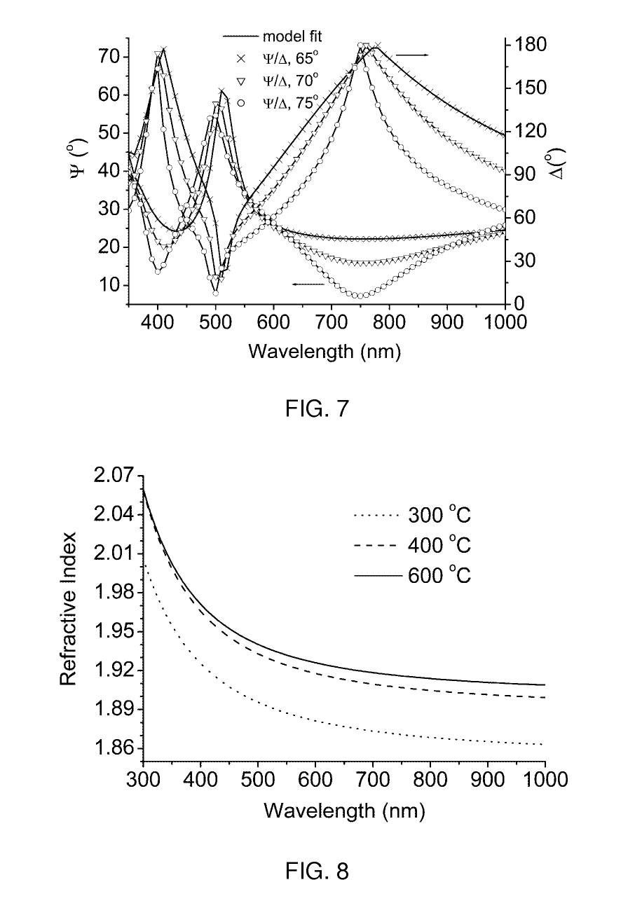

Ellipsometric data for 12-coat films were fit by modeling the bilayer HfO₂/SiO₂ with the parameters SiO₂ thickness (t_{SiO2}), HfO₂ thickness (t_{HfO2}), and Cauchy parameters A, B, C for dispersion (n(λ)=A+B/λ²+C/λ⁴) in the HfO₂ layer. Experimental and simulated ellipsometric spectra for a film annealed at 400° C. are shown in FIG. 7. The fitting results for 300, 400, and 600° C.-annealed films, along with values of mean square error (MSE) are listed in Table 1. As seen in FIG. 7, excellent agreement was achieved between the experimental data and the model, indicating that a homogeneous film has been produced. Because the derived values for the thickness of the SiO₂ layer were consistent with those observed from SEM images and the thermal growth conditions, there is a high level of confidence in the ellipsometric results. Also, as seen in Table 1, the film thickness shrank by 13% between 300 and 400° C. anneals and little thereafter. The predominant change occurring by 400° C. was consistent with the general density trend generated from the XRR measurements, cf., FIG. 6.

TABLE 1
Model Fitting Results for Thickness of SiO₂ (t_{SiO2}) and HfO₂ (t_{HfO2}),
HfO₂ Cauchy Parameters A, B, C, and Mean Square Error (MSE)

| Anneal | | | | | | |
|---|---|---|---|---|---|---|
| (° C.) | t_{SiO2} (nm) | t_{HfO2} (nm) | A | B | C | MSE |
| 300 | 201.3(3) | 112.1(2) | 1.854(2) | 8.6(9) × 10⁻³ | 4.7(9) × | 9.250 |
| | | | | | 10⁻⁴ | |
| 400 | 201.9(2) | 97.6(1) | 1.891(2) | 8.0(8) × 10⁻³ | 6.4(8) × | 8.106 |
| | | | | | 10⁻⁴ | |
| 600 | 202.7(2) | 94.3(2) | 1.901(2) | 7.3(9) × 10⁻³ | 6.3(9) × | 8.935 |
| | | | | | 10⁻⁴ | |

Refractive index (n) dispersion curves obtained from the model fit are shown in FIG. 8. The refractive indices at λ=550 nm for HfO₂ are 1.89, 1.92, and 1.93 for films annealed at 300, 400, and 600° C., respectively. These high refractive indices are comparable to those for vapor-deposited HfO₂ films. For example, n(550 nm)=1.85-1.98 and n(633 nm)=1.98 have been reported for electron-beam evaporated films and sputtered films, respectively.^{35,36} Corresponding values for ZrO₂ are 1.97 and 1.95 for films annealed at 300 and 500° C., respectively. The relative density of a film can be estimated by modeling the film as a combination of bulk material and a second phase (air or water) in void spaces via the effective optical medium approach represented by Eq. (1),³⁷

$$\frac{( {n}^{2} - {n}_{2}^{2} ) ( {n}^{2} + 2 {n}_{1}^{2} )}{( {n}^{2} + 2 {n}_{2}^{2} ) ( {n}_{1}^{2} - {n}^{2} )} = \frac{{q}_{1}}{1 - {q}_{1}} \qquad ( 1 )$$

where n is the refractive index for the film, n₁ for bulk HfO₂ (n₁=2.13),³⁵ n₂ for voids in the form of air (n₂=1), or water (n₂=1.33), and q₁ is the volume fraction of the bulk. Since q₁ directly depends on n₂, the most physically reasonable second phase should be chosen. On the basis of the FT-IR results, voids composed of water are assumed for the 300° C.-annealed film, and voids of air for the 400° C. and 600° C.-annealed films. Thus bulk volume fractions of 77%, 88%, and 88% for 300, 400° C. and 600° C.-annealed films, respectively, are derived. These values agree well with the relative densities determined from XRR: 78%, 86%, and 87%. Alternatively assuming air voids at 300° C. generates a bulk fraction of 86%, while assuming water voids at 400° C. gives a bulk fraction of 80%. These assumptions lead to large discrepancies with the results derived from XRR measurements. Therefore, FT-IR, XRR, and optical measurements are collectively consistent with the production of dehydrated and densified films after heating near 400° C. Similar analyses with ZrO₂, assuming air voids, reveal bulk fractions in the range of 86-87% for films annealed between 300° C. and 700° C.

The refractive indices of ˜260-nm thick HfO₂ films annealed in the range of 200-800° C. were also determined by fitting the thin-film interference fringes in the reflection and transmission spectra. The n(550 nm) values determined by fringe fittings agree to within 1% of those by ellipsometric analyses.

Electronic Device Fabrication and Characterization.

Metal-insulator-semiconductor (MIS) and metal-insulator-metal (MIM) capacitor test structures were constructed by spin-coating HfO₂ thin films onto degenerate, p-type Si substrates (0.008-0.016 Ωcm) and onto Si wafers coated with 500 nm of Ta, respectively. The capacitors were completed by thermally evaporating 200-nm thick circular Al contacts via a shadow mask (0.011 cm²) onto the annealed dielectrics. Relative dielectric constant and loss tangent were measured by using a Hewlett-Packard 4192A impedance analyzer. Leakage currents and breakdown fields were assessed by using a Hewlett-Packard 4140B picoammeter with a voltage ramp of 1 V/s.

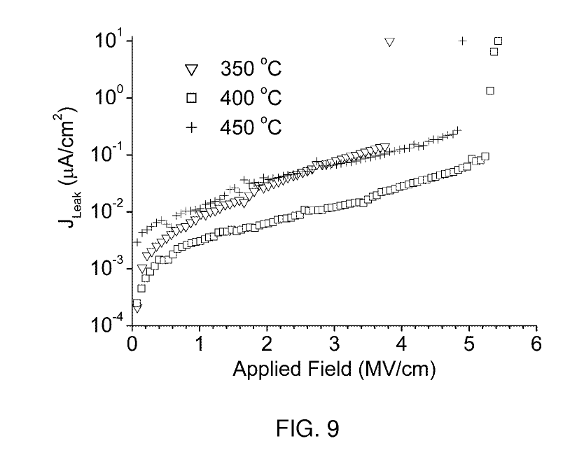

The dielectric properties of the HfO₂ films were first assessed by fabrication of MIS capacitor test structures, which were initially examined by small-signal capacitance and conductance measurements for determination of loss tangent (tan δ) and relative dielectric constant (∈ᵣ) at 1 kHz. Results for films ˜120-nm thick and annealed at selected temperatures are summarized in Table 2. The relative dielectric constant is approximately 13 for films annealed in the range of 300 to 600° C. ∈ᵣ values for vapor-deposited HfO₂ films are reported to span the range 12-25.^{10,11,32,38} The slightly higher dielectric constant for the films annealed at 300° C. compared with those annealed at 350 and 400° C. is attributable to residual, polarizable hydroxo groups; the high loss-tangent (9%) is also indicative of residual hydration in the films. Loss-tangent values decrease to <1% for films annealed from 350 to 450° C. and then increase to >5% for films annealed at higher temperatures. The latter increase is associated with crystallization and the formation of grain boundaries. Current-voltage measurements on the same devices were used to evaluate dielectric breakdown. In cases where catastrophic and irreversible current increases were not observed, a current limited breakdown is defined as the field strength where leakage current density exceeds 10 μA/cm². As seen in Table 2, the leakage current density is large for the 300° C.-annealed films. This result is once again related to incomplete dehydration. Catastrophic breakdown was observed for the thin-film capacitors annealed in the range 350-450° C. (FIG. 9). Here, all films demonstrated reliable breakdown ≧3.5 MV/cm and leakage current densities ≦10 nA/cm² at 1 MV/cm. Prior to breakdown, the small positive rise in current with increasing field may be associated with residual protons in the films. For films annealed at and above 500° C., leakage current densities increase and breakdown fields decrease as crystallization occurs, grains grow, and grain-boundaries develop, cf., FIGS. 4c and 4d. To assess the reproducibility of the dielectric properties in MIM structures, identical films were cast on Ta-coated substrates with annealing temperatures ≦350° C. The results were found to be equivalent to those with the Si substrates. The performance of films as thin as 20 nm was also assessed on Si substrates. Average leakage current and breakdown of 12 nA/cm² and 4 MV/cm, respectively, were observed for films annealed at 400° C.

TABLE 2
Electrical Characteristics of MIS Capacitors with ~120-nm HfO₂
Dielectrics Annealed in Air for 1 hour

| Anneal | tan δ | εᵣ | J_{Leak}^{a} | Breakdown^{b} |
|---|---|---|---|---|
| (° C.) | (%) | (1 kHz) | (nA/cm²) | (MV/cm) |
| 300 | 9 | 13 | 5000 | 1.2 (CL) |
| 350 | 0.8 | 12 | 10 | 3.5 |
| 400 | 0.7 | 12 | 3 | 5.5 |
| 450 | 0.7 | 13 | 5 | 4.5 |
| 500 | 5 | 13 | 67 | 2.9 |
| 600 | 6 | 13 | N/A | 0.8 (CL) |

^{a}J_{Leak} data were obtained at a field strength of 1 MV/cm.
^{b}CL stands for current limited breakdown, which is defined as the field strength where leakage current density equals 10 μA/cm², when catastrophic and irreversible current events are not observed.

TFTs were fabricated with solution-processed HfO₂ films as gate dielectrics and the amorphous oxide semiconductor indium gallium zinc oxide (IGZO) as active channels. Bottom-gate thin-film transistors (TFTs) were fabricated by rf sputtering through a shadow mask 50 nm of indium gallium zinc oxide (IGZO) channel materials onto 110-nm thick HfO₂ thin films on p-type Si substrates. HfO₂ films were produced via spin-coating with a final anneal of 400° C. Control devices were fabricated by depositing IGZO onto Si wafers having a 100-nm thick layer of SiO₂. The dielectric/semiconductor stacks were annealed at 300° C. for 1 h. Al source and drain contacts were thermally evaporated via a shadow mask; TFT dimensions were width=1000 μm and length=100 μm. The transistors were characterized in the dark with a Hewlett-Packard 4156C semiconductor parameter analyzer.

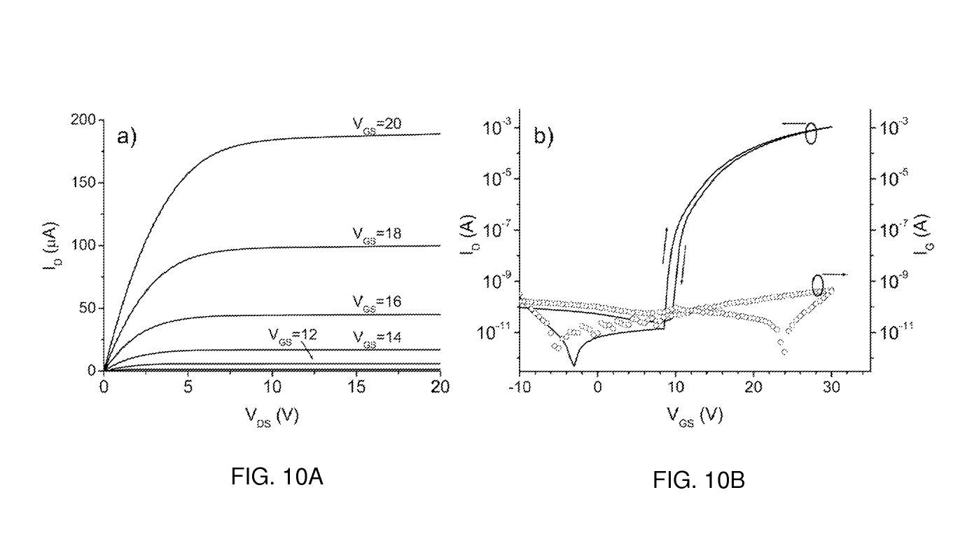

TFT performance (FIGS. 9a and 9b) was assessed through an analysis of the turn-on voltage (Vₒₙ), drain current on-to-off ratio (Iₒₙ/I_{off}), incremental channel mobility (μ_{inc}),³⁹ and subthreshold swing (S).⁴⁰ As shown in the output curve (FIG. 10a), qualitatively ideal transistor operation is evident from the field-effect current modulation (increasing I_{D} with increasing V_{GS}) and saturation in drain-to-source current at higher values of V_{DS}. As seen from the transfer curve (FIG. 10b), the device exhibited strong current switching, represented by the small S value (0.30 V/dec) and high Iₒₙ/I_{off} (>10⁷). Calculation of μ_{inc} from the transconductance yielded a peak value of 13.1 cm²/V·s at V_{GS}=25 V. Notably, the gate dielectric exhibited very low leakage current (<1 nA) even as the drive current reached mA levels, consistent with the performance of the HfO₂ films in the MIS and MIM capacitors. The device exhibited Vₒₙ=+8.5 V, higher than that (Vₒₙ=+2 V) for a SiO₂ control dielectric. This relatively large value of Vₒₙ was attributed to electron trapping states at the semiconductor-insulator interface, which may arise from plasma damage of the films during sputter deposition of IGZO. Such traps also contribute to the clockwise 1 V hysteresis in the transfer curve.

### Example 3

### Electron-Beam Patterning of Hf-Based Coating Material

U.S. Pat. Appl. Publ. 2011/0293888 A1 entitled “Patterned Inorganic Layers, Radiation Based Patterning Compositions and Corresponding Methods” to Stowers et al. and U.S. Pat. Appl. Publ. 2011/0045406 A1 entitled “Patterned Inorganic Layers, Radiation Based Patterning Compositions and Corresponding Methods” to Stowers et al. describe compositions and processes for directly patterning radiation-sensitive coating materials containing zirconium and hafnium. These materials contain zirconium, hafnium, a peroxide ligand, and a polyatomic anion.

Silicon wafers were O₂-plasma ashed prior to film deposition. Precursors were spin coated onto the wafers at 2000-3000 rpm for 30 s. An 80° C. post apply bake was conducted for 2 min following the spin coating. The resulting film thickness from this procedure was typically 30 nm. Exposures for line and pattern formation were conducted using a high voltage electron beam tool with a lithography system. A 2-min, 80° C. post-exposure bake was conducted after exposure. Development was performed in TMAH (tetramethyl ammonium hydroxide) or acid developer, followed by a thorough water rinse. Finally, the film was hard baked at 250° C. for 5 min.

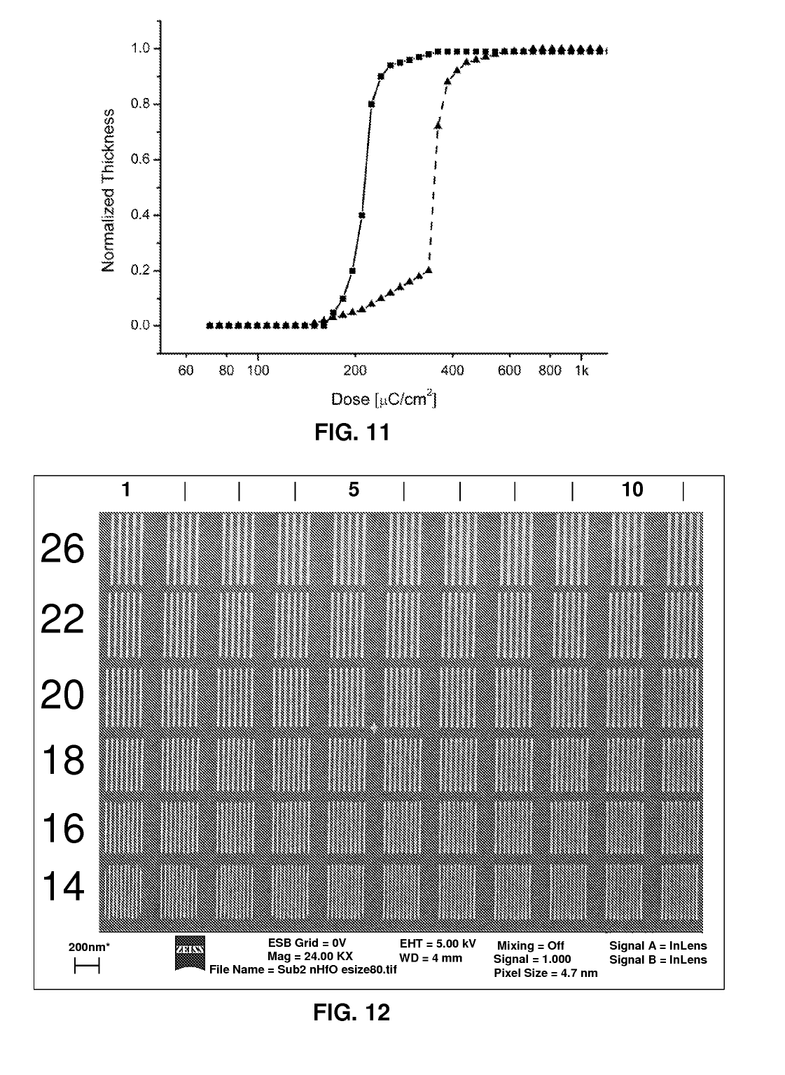

Contrast curves generated for exposing hafnium oxide nitrate (prepared as described in Examples 1 and 2) and hafnium oxide sulfate (prepared as disclosed in U.S. Patent Publication Nos. 2011/0293888 and 2011/0045406) coating materials with an electron beam are shown in FIG. 11. By comparing the solid and dashed lines, it is seen that the hafnium oxide nitrate exhibits a higher sensitivity, i.e., a higher contrast in dissolving unexposed versus exposed regions is achieved at a lower exposure dose, i.e., a two-fold improvement in sensitivity. This higher sensitivity is enabled in part by the designed high solubility of the coating material.

For safety and environmental concerns, a dilute acid or base developer is preferred over a concentrated acid or base developer for achieving high sensitivity and high contrast in patterning. When developed in base, the coating material of hafnium peroxide sulfate (dashed line, FIG. 11) exhibits a shallow slope in contrast at exposure doses between 150 and 336 μC/cm² prior to the onset of high contrast at 336 μC/cm². The shallow region of the contrast curve indicates incomplete development and dissolution of the coating material at intermediate doses. In this region, dissolution is inhibited by neutralization and condensation reactions that inhibit dissolution. Coating material that should be removed during the development process is left as “scum” or “footer” on the substrate, undesirable outcomes that limit capabilities for patterning features at small pitch.

Unlike the hafnium peroxide sulfate, the hafnium peroxide nitrate coating material exhibits an abrupt onset in contrast at a dose of 160 μC/cm² (solid line, FIG. 11) with development in a dilute acid. Hence, issues with scum and footer formation are reduced with the hafnium peroxide nitrate coating materials, enabling the use of a dilute developer for the production of high-resolution patterns. As shown in FIG. 12, dense lines and space patterns as small as 14-nm half pitch are readily produced with the materials under electron-beam exposure.

### Example 4

### EUV Patterning of Hf-Based Coating Material

Si wafers were O₂-plasma ashed prior to film deposition. Precusors were spin coated onto the wafers at 2000-3000 rpm for 30 s. An 80° C. post apply bake was conducted for 2 min following the spin coating. The resulting film thickness from this procedure was typically 30 nm. Exposures for line and pattern formation were conducted using an extreme ultraviolet lithography tool. A 2-min, 80° C. post-exposure bake was conducted after exposure. Development was performed in TMAH or acid developer, followed by a thorough water rinse. Finally, the film was hard baked at 250° C. for 5 min.

A method for forming aqueous precursors includes (a) dissolving a zirconium or hafnium salt in water, wherein the salt dissociates to form Zr⁴⁺ or Hf⁴⁺ cations and salt counterions, (b) forming a precipitate through the addition of an aqueous base, which forms base counterions and hydroxide ions in aqueous solution, (c) removing salt counterions and base counterions from the precipitate, (d) dissolving the precipitate in a monoprotic acid, and (e) adding aqueous hydrogen peroxide following one or more of the steps (a), (b), (c), or (d). The zirconium or hafnium salt may be zirconium oxide chloride, zirconium oxide nitrate, hafnium oxide chloride, or hafnium oxide nitrate.

In any or all of the above embodiments, the aqueous base may be NH₃(aq) or NaOH(aq). In any or all of the above embodiments, the aqueous base may be added batchwise. In any or all of the above embodiments, the monoprotic acid may have the formula HX(aq) where X is NO₃, Cl, Br, I, ClO₄, BrO₄, or IO₄. In some embodiments, dissolution in HX(aq) results in Zr/X or Hf/X>0.5. In any or all of the above embodiments, a sufficient quantity of H₂O₂ may be added to provide a Zr/O₂²⁻ ratio or a Hf/O₂²⁻ ratio ranging from 0.02 to 2.

In any or all of the above embodiments, removal of salt counterions and base counterions may include centrifuging or filtering the precipitate and washing the precipitate. In some embodiments, the zirconium or hafnium salt is zirconium oxide chloride or hafnium oxide chloride, and washing the precipitate with H₂O is repeated until a supernatant removed after washing the precipitate forms no visible AgCl precipitate when mixed with AgNO₃(aq).

In any or all of the above embodiments, the method may further include applying the precursor solution to at least one surface of a substrate to form a layer of a coating material comprising Zr⁴⁺ or Hf⁴⁺, water, peroxide, and monoprotic acid, thereby producing a coated substrate; and heating the coating material to expel water, monoprotic acid, and oxygen, thereby increasing the density of the coating material and forming a film on the coated substrate. In some embodiments, the at least one surface of the substrate is hydrophilic. The precursor solution may be deposited on the surface by spin coating, spray coating, aerosol chemical vapor deposition, dip coating, or ink-jet printing. In some embodiments, the coating material has a Zr/O₂²⁻ ratio or a Hf/O₂²⁻ ratio of between 0.02 and 2. The layer of coating material may have an average thickness from 2 nm to 40 nm. In some embodiments, the method further includes repeating a step of applying the precursor solution to the at least one surface of the substrate one or more times to form a coating material of a selected thickness. The coated substrate may be heated at a temperature from 70° C. to 200° C. for up to 5 minutes before repeating each step of applying the precursor solution. In some embodiments, heating the coating material includes heating at a temperature between 70° C. and 800° C. for 1 to 120 minutes.

In some embodiments, the coating material is heated at a temperature between 40° C. and 150° C. for up to 5 minutes, and the method includes patterning the film by exposing the film to radiation in a pattern to condense the film at exposed locations, subsequently heating the film to a temperature of 40° C. to 150° C. for 1 to 5 minutes, and contacting the film with a developer composition for a period of time effective to remove unexposed portions of the film, such as up to 180 seconds, thereby producing a patterned film. In some embodiments, the patterned film is heated at a temperature of at least 200° C. for a period of time sufficient to harden and fix the patterned film, such as for 1-10 minutes. The radiation may be ultraviolet light, light having a wavelength of 193 nm, extreme ultraviolet light, or an electron beam. In some embodiments, exposing the film to radiation in a pattern includes placing a mask between the radiation and the film, and directing the radiation through the mask to expose selected portions of the film. In some embodiments, exposing the film to radiation in a pattern includes scanning a laser beam or an electron beam over the film to expose selected portions of the film. In some embodiments, the developer composition includes nitric acid, hydrochloric acid, oxalic acid, hydrogen peroxide, tetramethyl ammonium hydroxide, or a combination thereof.

A film may comprise HfO₂ with a density of 7 g/cm³ to 10 g/cm³ or ZrO₂ with a density of 4 g/cm³ to 6 g/cm³. The film may be made by any one of the above embodiments. In some embodiments, the film has a thickness of >30 nm, a root mean square surface roughness of ≦0.5 nm as measured by atomic force microscopy or x-ray reflectivity, a leakage-current density ≦20 nA/cm² at 1 MV/cm, and a dielectric breakdown ≧3 MV/cm. In some embodiments, the film includes <0.05% (w/w) chloride. The film may have a refractive index of 1.8 to 2.0 at λ=550 nm. The film may have a relative dielectric constant of 12-15 at 1 kHz. In some embodiments, the film further includes up to 25% (v/v) water.

A film according to any or all of the above embodiments may be included in a device. In some embodiments, the device is a metal-insulator-semiconductor capacitor, is a metal-insulator-metal capacitor, or a thin-film transistor.

### REFERENCES

(1) Yuan, L.; Zhao, Y.-N.; Shang, G.-Q.; Wang, C.-R.; He, H.-B.; Shao, J.-D.; Fan, Z.-X. J. Opt. Soc. Am. 2007, 24, 538.
(2) Goncalves, R. R.; Carturan, G.; Zampedri, L.; Ferrari, M.; Montagna, M.; Chiasera, A.; Righini, G. C.; Pelli, S.; Ribeiro, S. J. L.; Messaddeq, Y. App. Phys. Lett. 2002, 81, 20.
(3) Robertson, J. Rep. Prog. Phys. 2006, 69, 327.
(4) Wilk, G. D.; Muller, D. A.; App. Phys. Lett. 2003, 83, 3984.
(5) Tang, C.; Tuttle, B.; Ramprasad, R. Phys. Rev. B 2007, 76, 073306.
(6) Cherkaoui, K.; Monaghan, S.; Negara, M. A.; Modreanu, M.; Hurley, P. K.; O'Connell, D.; McDonnell, S.; Hughes, G.; Wright, S.; Barklie, R. C.; Bailey, P.; Noakes, T. C. Q. J. Appl. Phys. 2008, 104, 064113.
(7) Zhong, L.; Zhang, Z.; Campbell, S. A.; Gladfelter, W. L. J. Mater. Chem. 2004, 14, 3203.
(8) Ohshita, Y.; Ogura, A.; Ishikawa, M.; Kada, T.; Hoshino, A.; Suzuki, T.; Machida, H.; Soai, K. Chem. Vap. Deposition 2006, 12, 130.
(9) Kuo, C. T.; Kwor, R.; Jones, K. M. Thin Solid Films 1992, 213, 257.
(10) Pereira, L.; Barquinha, P.; Fortunato, E.; Martins, R.; Kang, D.; Kim, C. J.; Lim, H.; Song, I.; Park, Y. Thin Solid Films 2008, 516, 1544.
(11) Lin, Y.-S.; Puthenkovilakam, R.; Chang, J.-P. Appl. Phys. Lett. 2002, 81, 2041.
(12) Swerts, J.; Peys, N.; Nyns, L.; Delabie, A.; Franquet, A.; Maes, J. W.; Elshocht, S. V.; Gendt, S. D. J. Electrochem. Soc. 2010, 157, G26.
(13) Kim, S.; Kim, J.; Choi, J.; Kang, H.; Jeon, H.; Bae, C. J. Vac. Sci. Technol. B 2006, 24, 1088.
(14) Aoki, Y.; Kunitake, T.; Nakao, A. Chem. Mater. 2005, 17, 450.
(15) Nishide, T.; Honda, S.; Matsuura, M.; Ide, M. Thin Solid Films 2000, 371, 61.
(16) Wang, K.-J.; Cheong, K.-Y. Appl. Surf Sci. 2008, 254, 1981.
(17) Blanc, P.; Hovnanian, N.; Cot, D.; Larbot, A. J. Sol-Gel Sci. Technol. 2000, 17, 99.
(18) Villanueva-Ibanez, M.; Le Luyer, C.; Parola, S.; Marty, O.; Mugnier, J. Rev. Adv. Mater. Sci. 2003, 5, 296.
(19) Zaharescu, M.; Teodorescu, V. S.; Gartner, M.; Blanchin, M. G.; Barau, A.; Anastasescu, M. J. Non-Cryst. Solids 2008, 354, 409.
(20) Blanchin, M. G.; Canut, B.; Lambert, Y.; Teodorescu, V. S.; Barau, A.; Zaharescu, M. J. Sol-Gel Sci. Technol. 2008, 47, 165.
(21) Wang, Z.-J.; Kumagai, T.; Kokawa, H.; Ichiki, M; Maeda, R. J. Electroceram. 2008, 21, 499.
(22) Anderson, J. T.; Munsee, C. L.; Hung, C. M.; Phung, T. M.; Herman, G. S.; Johnson, D. C.; Wager, J. F.; Keszler, D. A. Adv. Funct. Mater. 2007, 17, 2117.
(23) Meyers, S. T.; Anderson, J. T.; Hong, D.; Hung, C. M.; Wager, J. F.; Keszler, D. A. Chem. Mater. 2007, 19, 4023.
(24) Meyers, S. T.; Anderson, J. T.; Hung, C. M.; Thompson, J.; Wager, J. F.; Keszler, D. A. J. Am. Chem. Soc. 2008, 130, 17603.
(25) Meyers, S. T. Ph.D Thesis, Oregon State University, 2008.
(26) Stowers, J.; Keszler, D. A. Microelectron. Eng. 2009, 86, 730.
(27) Donovan, J. J.; Tingle, T. N. J. Microsc. Soc. Am. 1996, 2, 1.
(28) Hausmann, D. M.; Gordon, R. G. J. Cryst. Growth 2003, 249, 251.
(29) Jose, J.; Bushiri, M. J.; Jayakumar, K.; Vaidyan, V. K. AIP Conf Proc. 2008, 1075, 125.
(30) Southon, P. D.; Bartlett, J. R.; Woolfrey, J. L.; Stevens, M. G. Ceram. Trans. 1998, 18, 75.
(31) Ruh, R.; Corfield, P. W. R. J. Am. Ceram. Soc. 1970, 53, 126.
(32) Conley, Jr., J. F.; Ono, Y.; Tweet, D. J.; Zhuang, W. J. Appl. Phys. 2003, 93, 712.
(33) Hausmann, D. M.; Kim, E.; Becker, J.; Gordon, R. G. Chem. Mater. 2002, 14, 4350.
(34) Lenormand, P.; Lecomte, A.; Babonneau, D.; Dauger, A. Thin Solid Films 2006, 495, 224.
(35) Jerman, M.; Qiao, Z.; Mergel, D. Appl. Optics 2005, 44, 3006.
(36) Martinez, F. L.; Toledano-Luque, M.; Gandia, J. J.; Carabe, J.; Bohne, W.; Rohrich, J.; Strub, E.; Martil, I. J. Phys. D: Appl. Phys. 2007, 40, 5256.
(37) Mergel, D. Thin Solid Films 2001, 397, 216.
(38) Rauwel, E.; Clavel, G.; Willinger, M. G.; Rauwel, P.; Pinna N. Angew. Chem. 2008, 120, 3648.
(39) Hoffman, R. L. J. Appl. Phys. 2004, 95, 5813.
(40) Schroder, D. K., Semiconductor Materials and Device Characterization, 2^{nd} ed.; John Wiley and Sons: New York, 1998.
(41) Johnson, J. S.; Kraus, K. A. J. Am. Chem. Soc. 1956, 78, 3937.
(42) Zielen, A. J.; Connick, R. E. J. Am. Chem. Soc. 1956, 78, 5785.
(43) Toth, L. M.; Lin, J. S.; Felker, L. K. J. Phys. Chem. 1991, 95, 3106.
(44) Aberg, M.; Glaser, J. Inorg. Chim. Acta. 1993, 206, 53.
(45) Clearfield, A. Rev. Pure and Appl. Chem. 1964, 14, 91.
(46) Keramidas, V. G.; White, W. B. J. Am. Ceram. Soc. 1974, 57, 22.
(47) Matsui, K.; Suzuki, H.; Ohgai, M. J. Am. Ceram. Soc. 1995, 78, 146.
(48) Clearfield, A. J. Mater. Res. 1990, 5, 161.
(49) Colfen, H.; Schnablegger, H. Langmuir 2002, 18, 3500.
(50) Jiang, K.; Zakutayev, A.; Stowers, J.; Anderson, M. D.; Tate, J.; McIntyre D. H.; Johnson, D. C.; Keszler, D. A. Solid State Sci. 2009, 11, 1692.
(51) Connick, R. E.; McVey, W. H. J. Am. Chem. Soc. 1949, 71, 3182.
(52) Thompson, R. C. Inorg. Chem. 1985, 24, 3542.
(53) Gao, Y.; Masuda, Y.; Ohta, H.; Koumoto, K. Chem. Mater. 2004, 16, 2615.
(54) Henry, M.; Jolivet, J. P.; Livage, J. Struct. Bond. 2002, 77, 153.

1. A method for forming precursor solution for making a film, comprising:
dissolving a zirconium or hafnium salt in water, wherein the salt dissociates to form Zr⁴⁺ or Hf⁴⁺ cations and salt counterions,
forming a precipitate by adding an aqueous base, which forms base counterions and hydroxide ions in aqueous solution,
removing counterions from the precipitate,
dissolving the precipitate in a monoprotic acid, and
adding aqueous hydrogen peroxide following one or more of the preceding steps.

2. The method of claim 1, wherein the zirconium or hafnium salt is zirconium oxide halide, zirconium oxide nitrate, hafnium oxide halide, or hafnium oxide nitrate.

3. The method of claim 1, wherein the aqueous base is NH₃(aq) or NaOH(aq).

4. The method of claim 1, wherein the aqueous base is added batchwise.

5. The method of claim 1, wherein the monoprotic acid has the formula HX(aq) where X is NO₃, Cl, Br, I, ClO₄, BrO₄, or IO₄.

6. The method of claim 5, wherein dissolution in HX(aq) produces a Zr/X or Hf/X ratio>0.5.

7. The method of claim 1, wherein a sufficient quantity of H₂O₂ is added to provide a Zr/O₂²⁻ ratio or a Hf/O₂²⁻ ratio ranging from 0.02 to 2.

8-9. (canceled)

10. The method of claim 1, further comprising:
applying the precursor solution to at least one surface of a substrate to form a layer of a coating material comprising Zr⁴⁺ or Hf⁴⁺, water, peroxide, and monoprotic acid, thereby producing a coated substrate; and
heating the coating material to expel water, monoprotic acid, and oxygen, thereby increasing the density of the coating material and forming a film on the coated substrate.

11-16. (canceled)

17. The method of claim 10, wherein the coating material is heated at a temperature between 70° C. and 800° C. for 1 to 120 minutes.

18-29. (canceled)

30. A film made by the method of claim 10, comprising:
HfO₂ with a density of 7 g/cm³ to 10 g/cm³ or ZrO₂ with a density of 4 g/cm³ to 6 g/cm³, wherein the film has
a thickness of >30 nm;
a root mean square surface roughness of ≦0.5 nm as measured by x-ray reflectivity; and
a refractive index of 1.8 to 2.0 at λ=550 nm.

31. The film of claim 30, further comprising <0.05% (w/w) chloride.

32. The film of claim 30, having:
a leakage-current density ≦20 nA/cm² at 1 MV/cm;
a dielectric breakdown ≧3 MV/cm; and
a relative dielectric constant of 12-15 at 1 kHz in a metal-insulator-metal or metal-insulator-semiconductor capacitor.

33. (canceled)

34. The film of claim 29, further comprising up to 25% (v/v) water.

35. A film, comprising:
HfO₂ with a density of 7 g/cm³ to 10 g/cm³ or ZrO₂ with a density of 4 g/cm³ to 6 g/cm³, wherein the film has
a thickness >30 nm;
a root mean square surface roughness of ≦0.5 nm as measured by atomic force microscopy or x-ray reflectivity; and
a refractive index of 1.8 to 2.0 at λ=550 nm.

36. The film of claim 35, having:
a leakage-current density ≦20 nA/cm² at 1 MV/cm;
a dielectric breakdown ≧3 MV/cm; and
a relative dielectric constant of 12-15 at 1 kHz in a metal-insulator-metal or metal-insulator-semiconductor capacitor.

37. (canceled)

38. The film of claim 35, further comprising <0.05% (w/w) chloride.

39. The film of claim 35, further comprising up to 25% (v/v) water.

40. A device comprising a film according to claim 35.

41. (canceled)

42. The device of claim 40, wherein the device is a metal-insulator-semiconductor capacitor or a metal-insulator-metal capacitor.

43. (canceled)

44. The device of claim 40, wherein the device is a thin-film transistor.
